(19) United States
(12) Patent Application Publication
(10) Pub. No.: US 2024/0305257 A1
(43) Pub. Date: Sep. 12, 2024

(54) Isolating amplifier apparatus

(71) Applicant: Teknologian tutkimuskeskus VTT Oy, Espoo (FI)

(72) Inventor: Joonas Govenius, Espoo (FI)

(21) Appl. No.: 18/289,239

(22) PCT Filed: Apr. 28, 2022
(86) PCT No.: PCT/FI2022/050278

§ 371 Date: Nov. 2, 2023

(30) Foreign Application Priority Data
May 5, 2021 (FI) 20215530

(51) Int. Cl. H03F 7/00; H03F 19/00; H10N 60/12

(52) U.S. Cl. CPC H03F 7/00; H03F 19/00; H10N 60/12; H03F 2200/198; H03F 2200/372

(57) ABSTRACT

According to an example aspect of the present invention, there is provided an isolating amplifier apparatus comprising a first 2×2 hybrid coupler and a second 2×2 hybrid coupler, each 2×2 hybrid coupler having a first input port, a second input port, a first output port and a second output port, a first travelling wave parametric amplifier, TWPA, comprising an input connected to the first output port of the first 2×2 hybrid coupler and an output connected to the first input port of the second 2×2 hybrid coupler, and a second travelling wave parametric amplifier, TWPA, comprising an input connected to the second output port of the first 2×2 hybrid coupler and an output connected to the second input of the second 2×2 hybrid coupler.

### FIELD

The present disclosure relates to traveling wave parametric amplifiers, TWPAS.

### BACKGROUND

Parametric amplifiers are in effect mixers, wherein a weaker input signal may be amplified by mixing it with stronger pump tone, producing a stronger output signal as a result. Parametric amplifiers rely on a nonlinear response of a physical system to generate amplification. Such amplifiers may comprise standing wave parametric amplifiers or traveling wave parametric amplifiers, TWPAs, wherein a traveling wave parametric amplifier uses a distributed nonlinearity along a waveguide and the signal travels unidirectionally, in the ideal case. The distributed nonlinearity may consist of a continuous nonlinear material, or a series of many nonlinear lumped elements, distributed along a transmission line, such as a coplanar waveguide, for example. In case the nonlinear elements comprise Josephson junctions, the amplifier may be referred to as a Josephson traveling wave parametric amplifier, JTWPA. In a JTWPA, the Josephson junctions are maintained in the superconducting state and carry a supercurrent. In case the nonlinearity is provided by using a high-kinetic inductance material, such as NbTiN, then the amplifier may be referred to as a kinetic inductance travelling-wave amplifier. In the optical domain, the nonlinearity is typically provided by nonlinear crystals, and travelling wave parametric amplifiers are often referred to as simply optical parametric amplifiers, without emphasis on their travelling wave nature.

### SUMMARY

According to some aspects, there is provided the subject-matter of the independent claims. Some embodiments are defined in the dependent claims.

According to a first aspect of the present disclosure, there is provided an isolating amplifier apparatus comprising a first 2×2 hybrid coupler and a second 2×2 hybrid coupler, each 2×2 hybrid coupler having a first input port, a second input port, a first output port and a second output port, a first travelling wave parametric amplifier, TWPA, comprising an input connected to the first output port of the first 2×2 hybrid coupler and an output connected to the first input port of the second 2×2 hybrid coupler, and a second travelling wave parametric amplifier, TWPA, comprising an input connected to the second output port of the first 2×2 hybrid coupler and an output connected to the second input of the second 2×2 hybrid coupler.

According to a second aspect of the present disclosure, there is provided a method, comprising using an isolating amplifier apparatus according to the first aspect as an amplifier by connecting the first input of the first 2×2 hybrid coupler to a signal source, feeding a pump tone to the first or to the second input of the first 2×2 hybrid coupler, and by extracting an idler tone as an amplified signal from the first output of the second 2×2 hybrid coupler, and by dissipating an amplified signal from the second output of the second 2×2 hybrid coupler.

### BRIEF DESCRIPTION OF THE DRAWINGS

FIG. 1 illustrates an example system useful for illustrating how the operating principle of the invention compares to an interferometer;

FIG. 2 illustrates an example apparatus in accordance with at least some embodiments of the present invention;

FIG. 3 illustrates a system in accordance with at least some embodiments of the present invention, and

FIG. 4 illustrates a system in accordance with at least some embodiments of the present invention.

### EMBODIMENTS

By connecting two TWPAs with two 2×2 hybrid couplers, as will be described herein, an isolating amplifier apparatus is obtained which provides low-noise amplification in a forward direction but does not convey noise or other signals in the reverse direction from the output of the isolating amplifier apparatus to the source of the signal to be amplified. This provides the effect and beneficial advantage that signal sources are better isolated from the surrounding environment, while gaining access to the information in the signals from the signal sources. This is obtained by a combination of phase control using frequency mixing and suitably arranged interference effects, as will be described in detail herein below. The present disclosure describes a circuit arrangement consisting of two or more individual TWPAs and standard passive components that together make up an isolating amplifier apparatus that suppresses noise propagating in the reverse direction, without compromising the desirable properties of the constituent TWPAs. The arrangement, in various embodiments, also automatically filters out the pump tone from the output signal, which would otherwise need to be done with separate filter components. In addition, the disclosed arrangement can, optionally, shift the output signal in frequency with respect to the input signal.

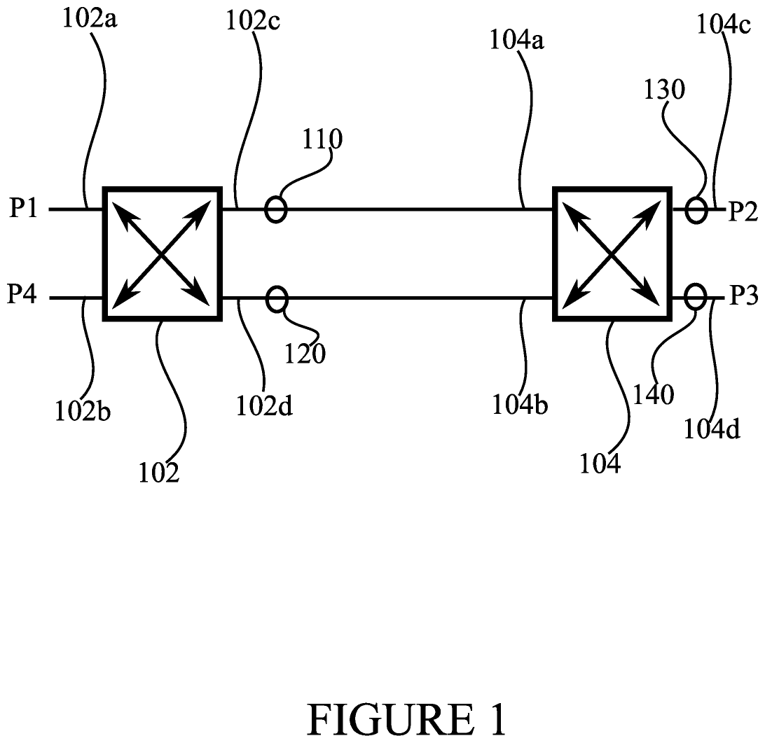

FIG. 1 illustrates an example system useful for illustrating how the operating principle of the invention compares to an interferometer. The apparatus in FIG. 1 is a reciprocal interferometer, where 2×2 hybrid couplers 102, 104 are connected together with waveguides 110, 120 as illustrated. While the expression “waveguide” is used in the present disclosure, it is not intended that this terminological choice would limit the area of applicability of the disclosed technology, despite the use in various frequency regimes of other terms for guided wave structures, such as transmission line, hollow waveguide, integrated optical waveguide or fibre-optic cable. In addition, the term hybrid coupler will be used instead of 2×2 hybrid coupler for the sake of brevity. In detail, the first input 102a of hybrid coupler 102 is fed from a source P1 and the second input 102b of hybrid coupler 102 is fed from a source P4. The first input 104a of hybrid coupler 104 is connected with the first output 102c of hybrid coupler 102 via waveguide 110, and the second input 104b of hybrid coupler 104 is connected with the second output 102d of hybrid coupler 102 via wave guide 120. Hybrid coupler 104 provides a first output 104c and a second output 104d, connected to loads P2 and P3, respectively. Sources P1, P4 and loads P2, P3 may be impedance matched.

The hybrid couplers may comprise 90 degree hybrids, which may also be referred to as 3 dB couplers, branchline couplers, or other terms referring to the physical implementation. Use of the term hybrid coupler or use of a 90 degree hybrid coupler in some of the examples is not intended to limit the area of applicability of the disclosed technology, despite different phase shifts being more typical for power splitters in certain frequency ranges, and despite different terms, such as beam splitter, used in certain frequency ranges. Furthermore, the relative phase of the outputs may depend on the input of the coupler, and the relative phase may be significantly different at different frequencies, which is relevant for TWPAs where relevant frequencies may span more than an octave. Defining features of hybrid couplers include that they are passive and each of the inputs is split equally in magnitude to the two outputs (thus the 3 dB terminology). In a 90 degree hybrid coupler the outputs are imparted with a relative phase shift of 90 degrees. The hybrid couplers may in practice have slight imperfections owing to manufacturing variability, such that the magnitude may not be split exactly equally, or the phase difference may be slightly different from the nominal value, however these effects do not prevent the operation of the present invention, although they lead to reduced performance. For example, the imparted phase difference for a 90 degree hybrid coupler may in practice be 90 degrees or 90 degrees±10 degrees, the amplitude imbalance could be e.g. 0.5 decibels, dB, and/or there may be e.g. 1 dB of losses or reflections. Practical imperfections of similar magnitude can be introduced to the isolating amplifier apparatus as a whole also by imperfections in other component, components indicated as identical in the examples not being exactly identical, or by the presence of additional short segments of passive waveguide not indicated in the examples.

In the illustrated apparatus, a signal fed from P1, entering the first input 102a, will thus propagate through the apparatus as follows: it will be split in hybrid coupler 102 to waveguides 110 and 120, such that it will have a relative phase of 90 degrees in waveguide 120, if we define the relative phase in waveguide 110 as zero. Each of these will split a second time at hybrid coupler 104 with another 90 degree relative phase shift added to the output that is diagonal to the input in the figure. Therefore, the output signal at the first output 104c of hybrid coupler 104 will be a sum of two equal-amplitude parts, the first coming from waveguide 110 with a relative phase of zero and a second coming from waveguide 120 with a relative phase of (90 deg+90 deg)=180 deg. Therefore, the two equal-amplitude parts have opposite phase and cancel each other at output 104c. In contrast, the output signal at the second output 104d of hybrid coupler 104 will be a sum of two equal-amplitude parts, the first coming from waveguide 120 with a relative phase of 90 deg, originating from hybrid coupler 102, and a second equal-amplitude part coming from waveguide 110 with a relative phase of 90 deg, originating from hybrid coupler 104. Therefore, the two equal-amplitude parts have the same sign and interfere constructively at output 104d. In other words, the signal fed from P1 is not seen at first output 104c in waveguide 130 at all and the signal fed from P1 will be directed in its entirety from first input 102a to second output 104d and waveguide 140.

Using similar logic, a signal fed from P4 into the second input 102b of hybrid coupler 102 winds up as an output signal at P2, the load connected to the first output 104c of hybrid coupler 104.

Thus energy may flow from P1 to P3 and from P4 to P2. The example system in FIG. 1 is symmetric with respect to the inputs and outputs and thus operates symmetrically in the other direction. This is called reciprocity. The results is that energy may flow from P3 to P1, and from P2 to P4. In the case of ideal components, energy cannot flow in the reverse direction from P2 to P1, for example, for the same reason, namely destructive interference.

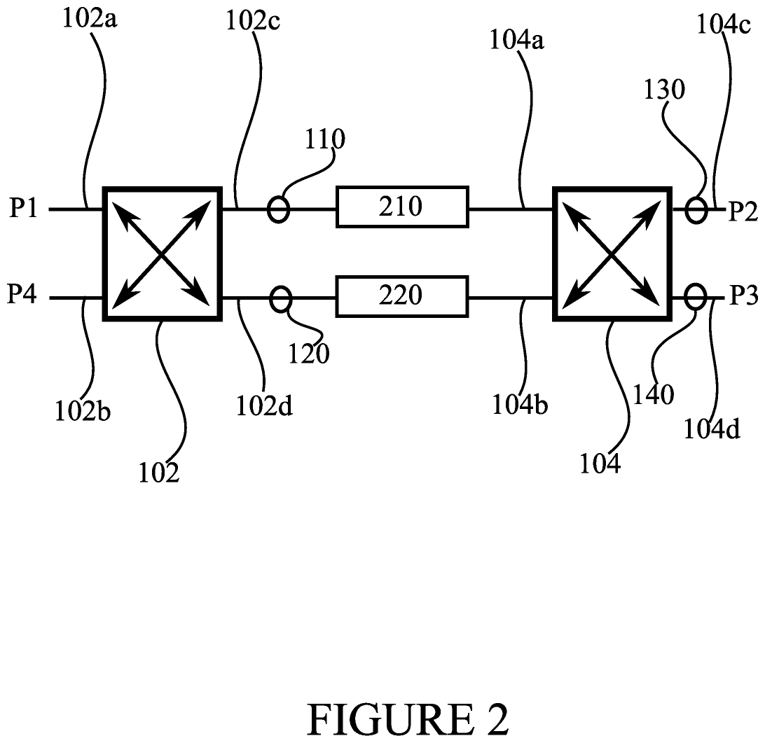

FIG. 2 illustrates an example apparatus in accordance with at least some embodiments of the present invention. Like numbering denotes like structure as in FIG. 1. TWPA 210 is connected with waveguide 110, such that the first output 102c of hybrid coupler 102 feeds the input of TWPA 210, and the output of TWPA 210 is conveyed to the first input 104a of hybrid coupler 104. Likewise, the second output 102d of hybrid coupler 102 is conveyed via waveguide 120 to the input of TWPA 220, and the output of TWPA 220 is conveyed into the second input 104b of hybrid coupler 104. TWPAs 210 and 220 are non-reciprocal elements providing gain only in the forward direction, but do not individually provide significant isolation beyond the dissipation of signals due to bidirectional dissipative losses, i.e. loss mechanisms within the TPWAs that do not depend on the propagation direction. In contrast, the apparatus of FIG. 2 as a whole provides significant additional isolation that is not associated with dissipation within the TWPAs themselves, as is discussed below. Bidirectional dissipative losses are generally undesirable for reasons such as directly reducing the net gain in the forward direction, increasing power dissipation, increasing the pump power requirement, and typically leading to additional noise at the output. In e.g. JTPWAs, the bidirectional losses can be low, for example in the range of 1 to 10 dB. Typical implementations of optical parametric amplifiers have much higher bidirectional losses, e.g. tens of dB, but lower loss optical parametric amplifiers may be developed in the future.

In a typical application of JTWPAs, dispersive readout of superconducting quantum bits, the phase and amplitude of a pulse of a few hundred microwave photons encodes the state of a superconducting quantum bit to be read out. Detecting such weak signals presents challenges owing to their low amplitude. In other applications, such as quantum teleportation, sensitivity even down to the level of single photons may be required. Therefore, suitable amplifiers may be employed to increase the amplitudes of received signals prior to their provision to following amplifier or detector elements, where the information encoded in these weak signals may be recovered. As another example, single-photon regime communication may be employed in communicating encryption keys in a secure manner using quantum communication, such that eavesdropping can be detected. Other embodiments of the present invention find application in amplifying signals that are not as weak as signals from qubits.

At least some embodiments of the present disclosure focus on a superconducting realization of the TWPA, where a significant fraction of the inductance of a transmission line is contributed by kinetic inductance or an array of Josephson junction based elements, known as Josephson elements, such as single-junctions, superconducting quantum interference devices, SQUIDs, or superconducting nonlinear asymmetric inductive elements, SNAILs. The Josephson junctions within the Josephson elements may be of multiple type, with different weak links placed between two superconductors. The Josephson elements provide the non-linearity that enables a mixing process which provides power gain for a weak signal that propagates along the same direction as a strong pump tone, typically in the radio frequency range for JTWPAs. The strength of the pump tone may be parametrized with the ratio between the pump current amplitude Ip and the design value of a critical current Ic of one arbitrarily chosen Josephson junction in the Josephson element. The nature of the non-linearity depends on the arrangement of Josephson junctions within the element. The simplest realization is the use of a single Josephson junction as the non-linear element: the associated Taylor expansion of the inductance is a constant plus a term proportional to (Ip/Ic)\hat{ }2, that is, a Kerr non-linearity. While the Kerr term results in a desired four-wave mixing process, it also changes the wavevectors of the rf tones as a function of the pump power, an effect that may be compensated with dispersion engineering. The balancing of the wavevectors, also called phase matching, allows an exponential increase of the TWPA gain as a function of the device length. The present invention is independent of the details of dispersion engineering used within the TWPAs. In addition to 4-wave mixing TWPAs based on the Kerr non-linearity, the invention is also applicable to 3-wave mixing TWPAs. Furthermore, JTWPAs are not the only kind of TWPA and the present disclosure is not limited to them. Indeed, TWPAs in the optical field may be implemented without superconducting parts and are equally in scope of the present invention. For example, the solution disclosed herein may be used in a microwave amplifier system, or in an optical amplifier system.

In general, TWPAs exist in at least two categories, namely based primarily on three-wave mixing, 3WM, and devices based primarily on four-wave mixing, 4WM. These mixing concepts are widely used in the field of non-linear optics. In 3WM, the pump tone at frequency f_p is at twice the frequency f_s, which is near the middle of the frequency band to be amplified. In 4WM, the pump tone is near the middle of the frequency band to be amplified.

While TWPAs amplify a signal in the forward direction, they inherently neither amplify nor attenuate a signal propagating in the reverse direction, from the output toward the input, except for bidirectional dissipative losses. This has the consequence that unwanted noise from components connected to the output of the TWPA may leak into the signal source being measured. Such noise may have an amplitude sufficient to meaningfully disturb sensitive elements at the signal source, such as qubits. Furthermore, preventing signals from propagating in the reverse direction from output to input in the isolating amplifier apparatus may be useful overall in environments that are not ideally impedance matched, as an amplifier with high gain in the forward direction and little isolation in the reverse direction can exhibit instability and other unwanted behavior, due to small reflections at the output and input. The propagation of power in the reverse direction may be controlled using additional non-reciprocal components such as isolators or circulators, but they in practice add losses, reflections, complexity, size and cost to the system as a whole.

Furthermore, in a TWPA producing gain, an idler tone f_i is generated at a frequency of f_p−f_s (3WM) or 2f_p−f_s (4WM). The generation of the idler tone is a feature inherent in the operation of TWPAs. Importantly for the present invention, the idler tone, which is effectively a copy of the amplified part of the signal at a different frequency, has a phase shift that depends on the phase of the pump tone, as it is a product of a mixing process. In an ideal parametric amplifier, the amplitude of the idler is √(G−1) times the input signal amplitude, if G is the power gain at the signal frequency. For 4-wave mixing, the relative idler phase shift is two times the relative pump phase, which is 180 degrees in total for an arrangement exemplified by FIG. 2 with 90 degree hybrid couplers and the pump fed in from one of the inputs of hybrid coupler 102. For 3-wave mixing, the relative idler phase shift is just the relative pump phase, which is 90 degrees for an arrangement exemplified by FIG. 2 with 90 degree hybrid couplers and with the pump fed in from one of the inputs of hybrid coupler 102. The amplified signal or pump tones do not receive phase shifts that depend on the phase of the pump. The idler tone is only generated in the forward direction in an ideal TWPA.

As was the case in the device of FIG. 1, in case the input signal to be amplified is fed from P1 to the first input 102a of hybrid coupler 102, then the amplified signal at the input frequency will wind up at P3, that is, the load connected to waveguide 140 at the second output 104d of hybrid coupler 104. This is the case since TWPAs 210, 220 amplify the signal between the hybrid couplers in the same manner in both signal paths, adding the same amount of phase delay in both. As a result, the signal in waveguide 140 is an amplified version of the input signal. Since the TWPAs need a pump tone, this pump tone may be conveniently input, for example, to the second input 102b of hybrid coupler 102, to cause equal-amplitude pump signals to propagate through both TWPAs 210, 220, triggering the amplification in both. Also, for the reasons described above in connection with FIG. 1, the pump tone introduced into the second input 102b of hybrid coupler 102 will wind up at the first output 104c of hybrid coupler 104 in waveguide 130.

On the other hand, the pump tone may be introduced into the first input 102a of hybrid coupler 102, and not to the second input 102b. In this case, the pump tone will wind up in the second output 104d of hybrid coupler 104, along with the amplified signal. In case the pump is introduced via the first input 102a, it may be combined with the input signal using a passive component, referred to as a pump coupler here. Examples of pump couplers include directional couplers with weak coupling that allows feeding in the pump tone without significantly attenuating the input signal. For example, a 10 dB, 20 dB or even more weakly coupled directional coupler may be used, as is known in the art. The directional coupler feeds the pump tone to hybrid coupler 102, but does not feed it to the signal source. A similar end result, may be achieved with a pump coupler consisting of passive but frequency-selective components, such as diplexers, that couple the narrow frequency band required for the pump to a different physical port than the signal. The pump tone may also be fed to both input ports of hybrid coupler 102, providing independent control of the pump tones fed to TWPAs 210 and 220, at the expense of more hardware components. Yet another variant, is to feed in independently controlled pumps to the TWPAs by adding one pump coupler between hybrid coupler 102 and TWPA 210, and a second pump coupler between hybrid coupler 102 and TWPA 220. Similarly, one or more additional pump couplers can be placed in the circuit after TWPAs 210 and 220 for the purposes of pump cancellation. Pump cancellation is a term used in the art to describe an arrangement where an additional tone at the pump frequency is fed to an additional directional coupler at the output of a TWPA, with the amplitude and relative phase of the additional tone adjusted such that the additional tone and the pump tone coming from the TWPA output interfere destructively at the output of the additional directional coupler.

We will next assess how the idler tone, generated in both TWPAs 210, 220 will behave in the apparatus illustrated in FIG. 2. Both TWPAs 210, 220 will generate an idler tone in the forward direction, toward hybrid coupler 104, with the phase of the idler determined by both the phase of the input signal and the phase of the pump tone. As the pump tone has different relative phase in waveguides 110, 210, and consequently in TWPAs 210, 220, the idler tone incident at the first input 104a of hybrid coupler 104 has a phase difference to the idler tone incident at the second input 104b of hybrid coupler 104. As noted above, for a 4-wave mixing TWPA, the relative idler phase shift is twice the relative pump phase, and in 3-wave missing, the relative idler phase shift is just the relative pump phase. If the pump is fed in from one of the inputs of the hybrid coupler 102, these correspond to 180 deg and ±90 deg, respectively, when 90 degree hybrids are used. The sign depends on convention. If one of the other pump coupler schemes described above is used, other phase shifts can be engineered, which may be useful especially in the case of alternative hybrid coupler types, the case of 3WM TWPAs, or the case that some of the components are asymmetric or otherwise nonideal.

Consequently, in the example case of 90 degree hybrids and feeding the pump in from input 102a of hybrid coupler 102, the relative phases of the idlers are as follows: The relative phase of the idler generated in TWPA 220 is 90 deg+2×90 deg=270 deg (4WM) or 90 deg+1×90 deg=180 deg (3WM), since the relative phase of the signal is 90 degrees and the relative phase of the pump is also 90. The relative phase of the pump and the relative phase of the idler in TWPA 210 are defined as zero. At the first output 104c of hybrid coupler 104, the two equal-amplitude idlers therefore have relative phases equal to zero, for the first part originating from TWPA 210, and 270 deg+90 deg=360 deg (4WM) or 180 deg+90 deg=270 deg (4WM), for the second part originating from TWPA 220. In the case of 4WM, the equal-amplitude idlers therefore interfere constructively and all of the idler power flows into the first output 104c of the hybrid coupler 104. In the case of 3WM, the equal-amplitude idlers are a quarter of a period out of phase, which implies that half of the total idler power flows into the first output 104c of the hybrid coupler 104. As a corollary, none (4WM) or half (3WM) of the total idler power flows into the second output 104d of the hybrid coupler 104.

The apparatus of FIG. 2, in the example case of 90 degree hybrids and feeding the pump in from input 102a of hybrid coupler 102, therefore directs all (4WM) or half (3WM) of the idler power to the first output 104c of hybrid coupler 104. This is due to the pump-dependent phase shift the idler obtains in the TWPAs. Since the idler is effectively a copy of the amplified input signal, except for a factor of approximately √(G−1)/√G difference in amplitude and a different frequency, the idler may be used as the true output of the isolating amplifier apparatus. Waveguide 140 may be connected to a termination resistor or other impedance-matched component, into which the amplified signal may be dissipated. In the case of 3WM, and the example case of 90 degree hybrids and feeding the pump in from input 102a of hybrid coupler 102, half of the idler power also flows into the termination of waveguide 140 but this only reduces the effective gain of the apparatus by 3 dB. If the pump tone is fed via input 102a, it will be directed to waveguide 140 as well. In case the pump is fed via input 102b, it will wind up in waveguide 130 with the idler. All (4WM) or half (3WM) of the idler is retrieved in both cases from waveguide 130, which is the output of the isolating amplifier apparatus. This arrangement provides the technical benefit that noise, or any other waveform, propagating into output 104c, is directed out of the isolating amplifier apparatus via input 102b of hybrid coupler 102. Input 102b may be terminated with a resistor or another impedance-matched component. In other words, noise impinging on output 104c of the apparatus does not wind up in the signal source connected to input 102a of hybrid coupler 102.

The only noise propagating in the reverse direction into input 102a of the hybrid coupler 102, and thus into the signal source, is noise from the termination of waveguide 140, in the case of ideal components. In case the termination is an impedance-matched resistor, the noise may consist of only thermal noise and quantum mechanical zero-point fluctuations. Manufacturing imperfections of all of the components in FIG. 2 may cause imperfect interference effects, reflections and minor losses within the components, leading to less than perfect isolation between the output and the input of the isolating amplifier apparatus, and generation of noise within the apparatus itself. Even with these imperfections, the isolation between the output and the input of the apparatus may be significant, for example 10 dB, 20 dB, or even better.

Notably, the disclosed mechanism for isolation is distinct from isolation methods employing the idler tone, but where frequency selective filtering is essential to providing the isolation. In the present invention, no frequency selective filtering is mandatory. Rather, the isolation in the present invention originates from interference effects and is more akin to Faraday rotation based isolators, but with Faraday-effect-based non-reciprocal phase modulation replaced by the non-reciprocal generation of idler tones in TWPAs, with phase controlled by the phase of the pump. Use of parametric conversion processes to create isolators using resonant parametric converters is also possible, but these are also substantially different from the presently disclosed solution since TWPAs are not resonant devices. The term travelling wave is by definition essentially opposite to resonant. In addition, a distinguishing feature of the present invention is that the isolating amplifier apparatus provides power gain, as long as the combination of exact hybrid type, pump coupling, and mixing process (4WM or 3WM) is such that an appreciable fraction of the idler power exits from an output different from the output that the amplified signal exists from. An appreciable fraction here may be any fraction larger than approximately 1/√(G−1), such that the output power is higher than, or approximately equal to, the original input signal power. A counter example of a non-isolating amplifier apparatus would be the arrangement of FIG. 2 but with 180 degree hybrids 102 and 104, 4WM TWPAs 210 and 220, and pump fed in from either input 102a or 102b. In that case, the relative phase of the pumps in the TWPAs is 180 degrees and the pump-dependent part of the idler relative phase is 2×180 deg=360 deg. Therefore, the idlers effectively receive no relative pump-dependent phase shift, modulo 360 deg, and would only inherit the phase of the signal, and would hence exit from the same port as the amplified signal. Depending on whether output 104c or 104d is used as the true output of the apparatus, the apparatus would therefore either not amplify or it would not isolate, for this specially chosen combination of components.

If the compromise of 3 dB reduction in gain in the case of 3WM is not desirable in the example discussed above, a pump signal can be fed to both inputs of hybrid coupler 102, such that a relative phase shift close to 180 degrees can be engineered for the pump tones in TWPAs 210 and 220. In particular, feeding into the inputs of hybrid coupler 102 pump tones of equal frequency and amplitude but opposite sign (180 degree relative phase), results in a 180 degree relative phase shift of the pump signals propagating through TWPAs 210 and 220. When a pump signal is fed to both inputs of hybrid coupler 102, the inputs may be fed from a single pump tone generator combined with passive components for choosing the relative amplitudes and phases, or each of the two inputs may be fed from a separate pump tone generator. The pump may also be fed to TWPAs 210 and 220 using separate pump couplers between the TWPAs and hybrid coupler 102. The idler from output 104c may be used as the output of the isolating amplifier apparatus also in the case of 3WM.

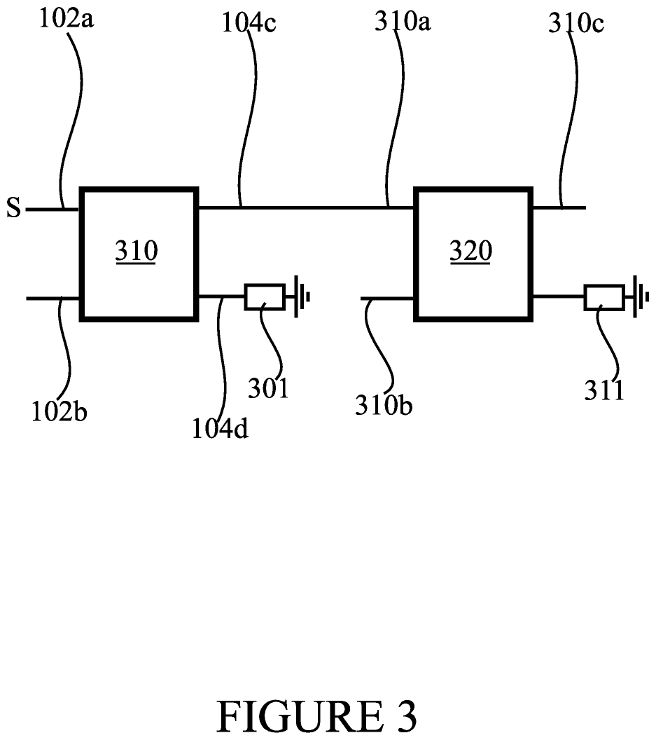

FIG. 3 illustrates a system in accordance with at least some embodiments of the present invention. The system comprises two isolating amplifier apparatuses as illustrated in FIG. 2. These devices are denoted amplifier 310 and amplifier 320 in the figure. Therefore, each of amplifiers 310 and 320 comprises two TWPAs and two hybrid couplers, as illustrated in FIG. 2. The inputs and outputs are separately drawn for the sake of clarity. Signal S is provided into input 102a, and pump into input 102b. The combined pump and idler of amplifier 310 is output via output 104c and directed to the first input 310a of amplifier 320, which provides a second stage of amplification. An additional pump tone may be further provided into the second input 310b of the first hybrid coupler of amplifier 320, or it may be terminated with a matched resistor. The unused amplified signals are terminated in resistors 301, 311, as illustrated, and the overall output, the idler from 320, is obtained from output 310c of amplifier 320, this being the first output of the second hybrid coupler of amplifier 320. The isolating amplifier apparata 310 and 320 may be identical, or may have different parameter values such as gain, for example.

An amplifier sequence is not limited to two stages, as illustrated in FIG. 3, rather, there may be any number of stages depending on the application. Noise propagating in the reverse direction into output 310c ends up in input 310b. Likewise noise propagating in the reverse direction into output 104c ends up in input 102b, and not the signal source which is connected to input 102a. Noise impinging on the output of the last stage is therefore suppressed exponentially in the number of amplifier stages, as it propagates in the reverse direction through the amplifier sequence. Advantageously for some use cases, with an even number of stages and identical pump frequencies, the output idler frequency is also the same as the original signal input frequency. In other applications, it is advantageous to separate the output and input frequencies. If the number of stages is odd and all pump frequencies are the same, the output frequency is equal to the idler frequency in the first pair of TWPAs. If the different stages are pumped at different frequencies, a nearly arbitrary output frequency from the last stage may be obtained by suitably selecting the pump frequencies in each stage.

Forward gain of the amplifier sequence scales with the number of stages as expected for independent amplifiers. That is, the idler power gains √(G−1) for the different stages are multiplied to obtain the approximate total gain. As an incidental benefit, in the systems of FIGS. 2 and 3, dynamic range is increased by 3 dB compared to the power handling of an individual TWPA.

As an implementation option, the components of the system of FIG. 3 could be implemented monolithically as a single integrated circuit. Alternatively, they may be implemented, for example, as discrete chips on a common printed circuit board, as separate chips in a flip-chip bonded module, or as separate connectorized components connected by discrete waveguides.

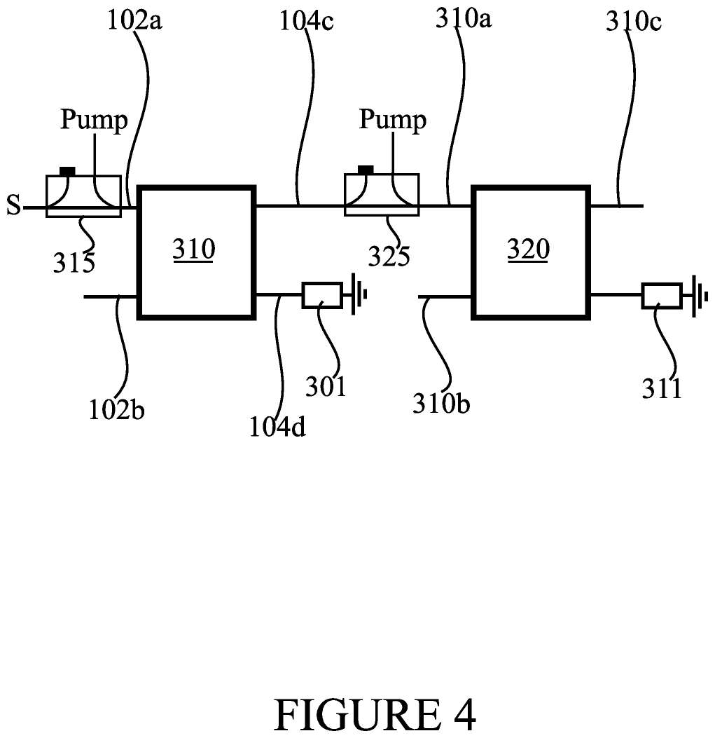

FIG. 4 illustrates a system in accordance with at least some embodiments of the present invention. Like numbering denotes like structure as in FIG. 3. The amplifier sequence of FIG. 4 differs from the one in FIG. 3 in the way the pump tones are fed into the amplifier stages. In detail, the pump tones are introduced into inputs 102a and 310a via directional couplers 315 and 325, respectively. The directional couplers direct the pump tone in the desired forward direction, rather than toward the signal source S. Providing the pump tones from these inputs provides the benefit, as discussed herein above, that the pumps wind up in resistors 301, 311, and thus the pump need not be separated from the output idler tones. Furthermore, pumping of the different stages 310 and 320 then becomes independent. As in the single stage case discussed above, it is also possible to feed the pump to both inputs of each stage to further engineer the pump signals within each arm of each stage. It is also possible to use pump couplers different from directional couplers, such as diplexers, as discussed above. Furthermore, pump couplers could be placed at other locations, such as between the hybrid couplers and the TWPAs, as also discussed above.

In general, there is provided an apparatus comprising a first hybrid coupler and a second hybrid coupler, each hybrid coupler having a first input port, a second input port, a first output port and a second output port, a first travelling wave parametric amplifier, TWPA, comprising an input connected to the first output port of the first hybrid coupler and an output connected to the first input port of the second hybrid coupler, and a second travelling wave parametric amplifier, TWPA, comprising an input connected to the second output port of the first hybrid coupler and an output connected to the second input of the second hybrid coupler. The first TWPA and the second TWPA may be similar, in particular, they may have the same operating parameters, such as gain.

The apparatus may be used as an isolating amplifier by connecting the first input of the first hybrid coupler to a signal source, by feeding a pump tone to the first or to the second input of the first hybrid coupler, or both, and by extracting an idler tone as an amplified output from the first output of the second hybrid coupler, and by dissipating an amplified signal from the second output of the second hybrid coupler. It is to be understood that the pump tones for the first and second TWPA can be fed in at multiple alternative locations, such as between the first hybrid coupler and the first TWPA and between the first hybrid coupler and the second TWPA, without meaningfully changing the principle of operation.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of numerical figures, component types, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in low-noise signal amplification.

### Acronyms List

3WM three-wave mixing
4WM four-wave mixing
JWTPA Josephson TWPA
TWPA travelling wave parametric amplifier

### REFERENCE SIGNS LIST

| 102a, 102b | first and second inputs to 2 × 2 hybrid coupler 102 |
|---|---|
| 102c, 102d | first and second outputs to 2 × 2 hybrid coupler 102 |
| 104a, 104b | first and second inputs to 2 × 2 hybrid coupler 104 |
| 104c, 104d | first and second outputs to 2 × 2 hybrid coupler 104 |
| 102, 104 | 2 × 2 hybrid couplers |
| 110, 120, | waveguides |
| 130, 140 | |
| 210, 220 | TWPAs |
| 310, 320 | isolating amplifiers |
| 301, 311 | termination resistors |
| 315, 325 | directional couplers |

### CITATION LIST

[1] A. Kamal, “Nonreciprocity in active Josephson circuits”, Ph. D thesis. Yale University (2013)
[2] Macklin et al., “A near-quantum-limited Josephson traveling-wave parametric amplifier” Science 350, 307 (2015).
[3] K. M. Sliwa et al., “Reconfigurable Josephson Circulator/Directional Amplifier”, Phys. Rev. X 5, 041020 (2015).
[4] M. P. Westig and T. M. Klapwijk, “Josephson Parametric Reflection Amplifier with Integrated Directionality,” Phys.Rev. Applied 9, 064010 (2018). DOI:10.1103/PhysRevApplied.9.064010

1. An isolating amplifier apparatus comprising:
a first 2×2 hybrid coupler and a second 2×2 hybrid coupler, each 2×2 hybrid coupler having a first input port, a second input port, a first output port and a second output port;
a first superconducting travelling wave parametric amplifier, TWPA, comprising an input connected to the first output port of the first 2×2 hybrid coupler and an output connected to the first input port of the second 2×2 hybrid coupler, and
a second superconducting travelling wave parametric amplifier, TWPA, comprising an input connected to the second output port of the first 2×2 hybrid coupler and an output connected to the second input port of the second 2×2 hybrid coupler,
wherein a pump tone is coupled to the first or to the second input port of the first 2×2 hybrid coupler, in that the isolating amplifier apparatus is configured to convey an idler tone to the first output port of the second 2×2 hybrid coupler, and to dissipate an input frequency signal from the second output port of the second 2×2 hybrid coupler.

2. The isolating amplifier apparatus according to claim 1, wherein the first and second TWPAs are 4-wave mixing TWPAs.

3. The isolating amplifier apparatus according to claim 1, wherein the first and second TWPAs are 3-wave mixing TWPAs.

4. The isolating amplifier apparatus according to claim 1, wherein the first output port of the second 2×2 hybrid coupler is configured to provide an output signal of the apparatus, and wherein the second output port of the second 2×2 hybrid coupler is coupled with a termination resistor.

5. The isolating amplifier apparatus according to claim 1, wherein the first input port of the first 2×2 hybrid coupler is coupled to a signal source to be amplified, and wherein the second input port of the first 2×2 hybrid coupler is coupled to a pump tone source.

6. The isolating amplifier apparatus according to claim 1, wherein the first input port of the first 2×2 hybrid coupler is coupled to a signal source to be amplified, and wherein a pump tone source is also coupled to the first input port of the first 2×2 hybrid coupler.

7. The isolating amplifier apparatus according to claim 1, wherein a first pump tone source is coupled to the first input port of the first 2×2 hybrid coupler and a second pump tone source is coupled to the second input port of the first 2×2 hybrid coupler.

8. The isolating amplifier apparatus according to claim 5, wherein the signal source comprises a cryogenic qubit, with or without additional isolators or filters in between.

9. The isolating amplifier apparatus according to claim 1, wherein the superconducting TWPAs are Josephson junction based microwave TWPAs.

10. The isolating amplifier apparatus according to claim 1, wherein the isolating amplifier apparatus is built on a single integrated chip.

11. A system comprising the isolating amplifier apparatus according to claim 1 and at least one second isolating amplifier apparatus according to claim 1, wherein the isolating amplifier apparatus and the at least one second isolating amplifier apparatus form an amplifier chain, wherein in the amplifier chain a signal output of each isolating amplifier apparatus except the last one is coupled to a signal input of an immediately succeeding isolating amplifier apparatus and wherein each isolating amplifier apparatus in the chain is coupled with at most one immediately preceding and at most one immediately succeeding isolating amplifier apparatus in the chain.

12. The system according to claim 11, wherein the first input port of the first 2×2 hybrid coupler is coupled to a signal source to be amplified, and wherein the second input port of the first 2×2 hybrid coupler is coupled to a pump tone source, and wherein the system further comprises a second pump tone source coupled with a second input port of the first 2×2 hybrid coupler of each isolating amplifier apparatus.

13. The system according to claim 11, wherein the system further comprises an even number of isolating amplifier apparatuses forming the amplifier chain.

14. The system according to claim 11, wherein the first and second isolating amplifier apparatuses are built on a single integrated chip.

15. The isolating amplifier apparatus according to claim 1 or a system according to claim 11, wherein each of the 2×2 hybrid couplers is a 90-degree hybrid coupler.

16. A method, comprising using an isolating amplifier apparatus according to claim 1 as an amplifier by connecting the first input port of the first 2×2 hybrid coupler to a signal source, feeding a pump tone to the first or to the second input port of the first 2×2 hybrid coupler, and by extracting an idler tone as an amplified signal from the first output port (104c) of the second 2×2 hybrid coupler, and by dissipating an amplified signal from the second output port (104d) of the second 2×2 hybrid coupler.

17. The method according to claim 16, wherein the pump tone is fed to the first and to the second input ports of the first 2×2 hybrid coupler, there being a 180-degree phase difference in the pump tones fed to the first and second input ports of the first 2×2 hybrid coupler.
